(19) United States
(12) Patent Application Publication
(10) Pub. No.: US 2010/0269000 A1
(43) Pub. Date: Oct. 21, 2010

(54) METHODS AND APPARATUSES FOR MANAGING BAD MEMORY CELL

(75) Inventor: Yang-Sup LEE, Gunpo-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/763,626

(22) Filed: Apr. 20, 2010

(30) Foreign Application Priority Data
Apr. 21, 2009 (KR) 10-2009-0034653

(51) Int. Cl. G06F 12/00; G06F 12/02; G11C 29/04; G06F 11/22

(52) U.S. Cl. 714/718; 711/156; 711/E12.001; 711/202; 711/E12.002; 714/E11.145

(57) ABSTRACT

A method for managing a bad cell is provided. The method includes reading status data from a page buffer and detecting a location of a bad cell from the status data. The method may further include remapping a bad address for the bad cell to a spare address for a spare cell in the same page.

### CROSS-REFERENCE TO RELATED APPLICATIONS

This application claims priority to Korean Patent Application No. 10-2009-0034653 filed on Apr. 21, 2009, the subject matter of which is hereby incorporated by reference.

### BACKGROUND

Embodiments of the present inventive concept relate to a bad memory cell management technology, and more particularly, to methods and apparatuses capable of managing a bad memory cell by reusing a run-time bad block.

Conventional NAND flash memory basically allows for runtime bad block(s) of about two percent (2%) of total available memory space. Accordingly, when one or more runtime bad block is identified, a flash translation layer (FTL) uses one of a number of conventionally understood algorithm(s) to replace each runtime bad block with a new block.

As NAND flash memory becomes ever more densely integrated, the occurrence of runtime bad blocks increases. Unfortunately, when the percentage of runtime bad blocks rises above the 2% maximum allocation expectation, the FTL of conventional NAND flash memory can not replace the identified runtime bad block(s) with new block(s).

### SUMMARY

Embodiments of the inventive concept provide methods and related apparatuses capable of managing a bad memory cells included in runtime bad block(s) by essentially reusing the runtime bad block(s).

One embodiment of the inventive concept is directed to a method for managing a bad cell in a memory system comprising a controller and a memory device, wherein the memory device comprises a page buffer configured to store status data and a memory array including a plurality of pages, the method comprising; following an operation directed to a selected page among the plurality of pages, storing the status data in the page buffer all bits of the selected page, reading the status data from the page buffer, and detecting a location of a bad cell in a plurality of memory cells of the memory cell array corresponding to the selected page by reference to the status data.

Another embodiment of the inventive concept is directed to a controller comprising; a processing unit configured to generate a status check command and communicate the status check command to a memory device, and a Flash Translation Layer (FTL) configured to receive status data for a selected page from a page buffer of the memory device in response to the status check command, and detect a location of a bad cell in a memory array of the memory device using the status data.

Another embodiment of the inventive concept is directed to a method for managing a bad cell in a memory cell array of a memory device using a controller, the method comprising; recording a command number for a read command directed to a selected page of the memory cell array, detecting a bad cell in the selected page generating a read error in response to the read command, recording a number of detecting the read error caused by the bad cell, and remapping a bad address associated with the bad cell to a spare address associated with a spare cell based on the command number of the read command and the command number of an operation detecting the read error.

Another embodiment of the inventive concept is directed to a controller comprising; a processing unit configured to generate a read command and communicate the read command to a memory device, and a flash translation layer (FTL) configured to record a command number of the read command, detect a bad cell in a selected page of a memory cell array of the memory device causing a read error for the selected page, record a command number of a command detecting the read error, and remapping a bad address associated with the bad cell to a spare address associated with a spare cell based on the command numbers of the read command and the operation detecting the read error.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a block diagram of a memory system according to an embodiment of the inventive concept;

FIG. 2 conceptually illustrates one example of data generated in a page buffer during an erase/program failure;

FIG. 3 conceptually illustrates another example of data generated in a page buffer during an erase/program failure;

FIG. 4 is a flowchart summarizing a method for managing a bad cell according to an embodiment of the inventive concept;

FIG. 5 is a flowchart summarizing a method for managing a bad cell according to another embodiment of the inventive concept;

FIG. 6 conceptually illustrates a bad cell remapping method according to an embodiment of the inventive concept;

FIG. 7 conceptually illustrates an operating method for a memory system according to an embodiment of the inventive concept;

FIG. 8 is a flowchart summarizing a method for managing bad cell according to another embodiment of the inventive concept; and

FIG. 9 shows a block diagram of a memory system according to another embodiment of the inventive concept.

### DETAILED DESCRIPTION OF THE EMBODIMENTS

Reference will now be made in some additional detail to certain embodiments of the inventive concept, examples of which are illustrated in the accompanying drawings, wherein like reference numerals refer to the like or similar elements throughout. The embodiments are described below in order to teach the making and use of the general inventive concept by way of illustrated examples.

FIG. (FIG.) 1 is a block diagram of a memory system according to an embodiment of the inventive concept.

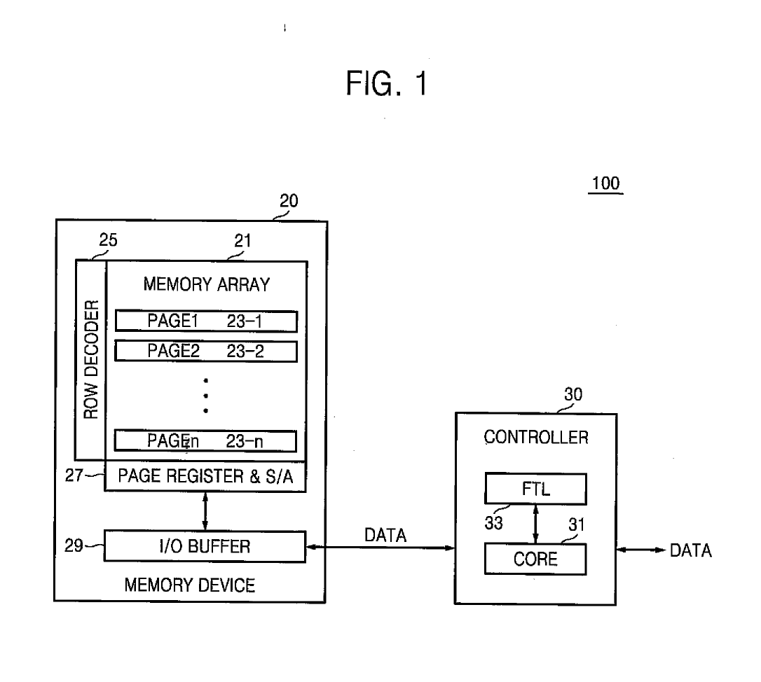

Referring to FIG. 1, a memory system 100 generally comprises a memory device 20 and a controller 30. The controller 30, which may be a central processing unit (CPU), a general processor, microprocessor, or custom controller capable of independently controlling the overall operation of the memory device 20. Those skilled in the art will recognize that other related circuits such as voltage generators, input/output circuits, etc., may be conventionally used in conjunction with the inter-operation between the memory device 20 and controller 30.

The memory device 20 includes a memory array 21, a row decoder 25, an access circuit 27, and an input/output (I/O) buffer 29. The memory device 20 may further include other components (not shown) required to communicate (i.e., send and/or receive) data with the controller 30.

The memory array 21 of FIG. 1 is divided into a plurality of pages 23-1 to 23-n, where “n” is a natural number. Each one of the plurality of pages 23-1 to 23-n may include a main region and a spare region. Each main region includes a plurality of word lines, a plurality of bit lines, and a plurality of non-volatile memory cells respectively connected between the word and bit lines and conventionally configured to store page data. Each spare region also includes a plurality of word lines, a plurality of bit lines and a plurality of non-volatile memory cells, but the memory cells are configured to store error check bits associated with at least a portion of the page data stored in the corresponding main region and capable of being used for remapping operations.

For example, assuming a main region storing 512 bytes and a spare region storing 16 bytes, a total resulting page size is 528 bytes. Those skilled in the art will recognize that page data may be variously sized in units of (e.g.) 512 bytes, 1024 bytes (or 1 KByte), 2048 bytes (or 2 KByte), 4096 bytes (or 4 KByte) or other multiples of 512 bytes.

The plurality of non-volatile memory cells (hereinafter individually or collectively referred to as “the memory cell”) incorporated within the memory array 21 may be Electrically Erasable Programmable Read-Only Memory (EEPROM), NAND flash memory, NOR flash memory, Magnetic RAM (MRAM), Spin-Transfer Torque MRAM, Conductive bridging RAM (CBRAM), Ferroelectric RAM (FeRAM), Phase Change RAM (PRAM), Resistive RAM (RRAM or ReRAM), Nanotube RRAM, Polymer RAM (PoRAM), Nano Floating Gate Memory (NFGM), holographic memory, Molecular Electronics Memory Device or Insulator Resistance Change Memory. Each one of the plurality of non-volatile memory cells may be configured to store a single bit of data or a plurality of bits.

The row decoder 25 is conventionally configured to supply at least one voltage to at least one word line among a plurality of word lines in the memory array 21 to execute a program operation, a write operation, a read operation, or an erase operation by decoding a row address received from the controller 30. A column decoder (not shown) may similarly supply at least one voltage to at least one bit line among a plurality of bit lines in the memory array 21 to execute the program operation, write operation, read operation or erase operation.

The access circuitry 27 is configured to communicate data between the memory array 21 and the I/O circuit 29 during a page read operation or a page program operation. The access circuitry 27 will generally and as conventionally understood include a page register (not shown) and a sense amplifier (not shown). The access circuit 27 may perform a program operation or a read operation on page basis using the page register and/or a sense amplifier. In contrast, an erase operation may be performed on block basis, where a block includes a plurality of pages. In certain embodiments, each block may include a plurality of pages formed in a well.

The access circuitry 27 is commonly referred to as a page buffer within embodiments of the inventive concept. The I/O buffer 29 is configured to communicate data between the access circuit 27 and the controller 30. The access circuit 27 may provide “read data” to the I/O buffer 29 as a result of performing a read operation. Analogously the access circuit 27 may hold “write data” received from the I/O buffer 29 during a program operation. The read data or write data will include a plurality of bits, e.g., a number of bits defined by the page size.

The controller 30 is further configured to detect the location of a “bad cell” from the read data provided by the access circuit 27, and then “remap” the address associated with the bad cell (i.e., the “bad cell address”) to a new address associated with a spare memory cell (i.e., the “spare cell address”). By remapping the bad cell address to a (good) spare cell address, the controller effectively replaces a bad cell located in the main region of a given page with a fully functional spare cell located in the spare region of the same page. Thereafter, the controller 30 will access the spare cell through the access circuit 27 during each succeeding program operation, write operation, read operation, or erase operation.

The controller 30 may include a function block, e.g., a flash translation layer (FTL) 33, which may perform an algorithm for reading the status data from the access circuit 27 under a control of a processing unit 31, which may generate various commands, and detecting a location of a bad cell from a read status data.

According to certain embodiments of the inventive concept, the CORE processing unit 31 and the FTL 33 may be respectively embedded in the controller 30 as separate and independent hardware (i.e., distinct integrated circuits), as associated hardware and firmware (i.e., hardware and controlling code stored on electronic recording medium), or as hardware/firmware/software.

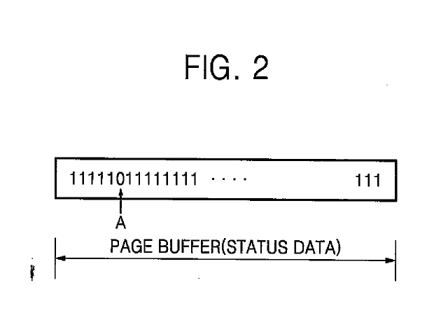

FIG. 2 conceptually illustrates data generated in a page buffer during an erase/program failure. For an ease of explanation, it is assumed that each bit value of the data, as applied to the page buffer 27, is supposed to be set to a “1” before an erase operation begins. It is further assumed that during the erase operation, the access circuit 27 unintentionally changes the logic state of one memory cell included in each one of the plurality of pages 23-1 to 23-n within a defined block from “1” to “0”.

Thus, an erase failure is generated to identify the block as a runtime bad block because the bad cell continuously stores a “0” when it should store a “1” during an erase operation. And the identified cell is noted as the bad cell generating the erase failure.

In the illustrated example of FIG. 2, it is assumed that a block includes 64 pages, each page includes 64 bits, and that each one of the 64 bits in each page of the block should be set to “1” during an erase operation. Unfortunately, the 6^{th} bit of each 64 page bits is constantly a “0” (event “A”). Accordingly, the memory cell associated with the 6^{th} bit of the 64 page bits is designated as a bad cell, and the controller 30 will remap the corresponding bad cell address for the memory cell associated with the 6^{th} bit of each the 64 page bits. Address remapping by the controller 30 effectively replaces the memory cell associated with the 6^{th} bit of each the 64 page bits with a spare cell selected from the spare region of each page.

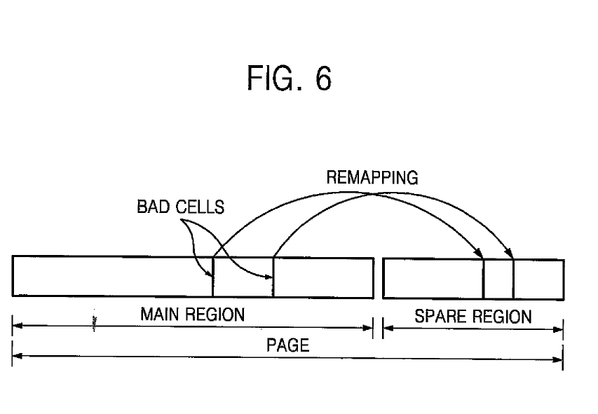

Thus, the controller 30 may accurately detect the location of a bad cell from the data generated by the access circuit 27 as the result of performing an erase operation, and then remap the bad cell address associated with the detected bad cell to a spare cell address associated with a (good) cell located in the spare region of the same page. One possible remapping operation will be described in some additional detail with reference to FIG. 6.

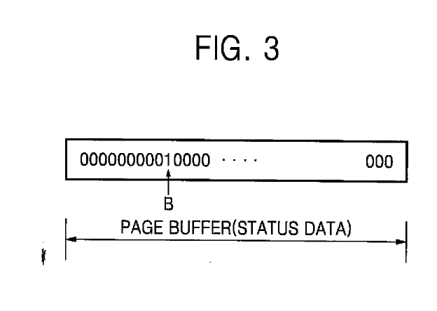

As illustrated in FIG. 3, the controller 30 may also accurately detect the location of a bad cell from the data generated by the access circuit 27 as the result of performing a program operation, and then remap the bad cell address associated with the detected bad cell to a spare cell address associated with a (good) cell located in the spare region of the same page. That is, instead of the uniformly “1” data that should be present in the page buffer during an erase operation, uniformly “0” write data may be communicated via the I/O buffer 29 to the access circuit 27 during a program operation. Accordingly, each bit value of the data apparent in the access circuit 27 is supposed to be set to 0 before a program operation is performed.

However, during the program operation, the access circuit 27 (or some external noise effect) may unintentionally change the state of data stored in one or more memory cells in each one of the plurality of memory cells forming pages 23-1 to 23-n. Thus, a program failure is generated identifying a runtime bad block since the state of at least one memory cell that should be a “0” is constantly a “1”.

For example, each of the plurality of memory cells of a first page 23-1 should be programmed to 0, and all memory cells except for the memory cell connected to a 10^{th} bit line are programmed to 0 (event “B”). Thus, the memory cell associated with 10^{th} bit of the 64 page bits (i.e., the memory cell connected to the sixth bit line and constantly exhibiting a logic state of “1”) is identified as a bad cell generating the program failure. Therefore, in response to the detected program failure, the controller 30 may analyze (or decode) the data apparent in the access circuit 27, and remap the bad cell address associated with the bad cell connected to the sixth bit line of the main region to a spare address associated with a spare cell in a spare region.

Thus, the controller 30 may accurately detect the location of a bad cell from the write data apparent in the access circuit 27 as a result of performing a program operation, and then remap the corresponding bad address for the detected bad cell to a spare address corresponding to a (good) spare cell in the corresponding spare region of the page.

With reference to FIG. 1 and the foregoing discussion of erase/program failures and the subsequent detection and replacement of bad cell(s), the processing unit 31 of controller 30 may be configured to generate a status check command, and a functional block within the controller 30, (e.g., FTL 33), may be configured to execute an algorithm reading the state of the data apparent in the access circuit 27 in response to the status check command. This data state reading may then be used to detect the location of a bad cell. Moreover, the functional block, (e.g., FTL 33), may be further configured to remap the bad cell address associated with the detected bad cell to a spare address associated with a spare cell under the control of the processing unit 31.

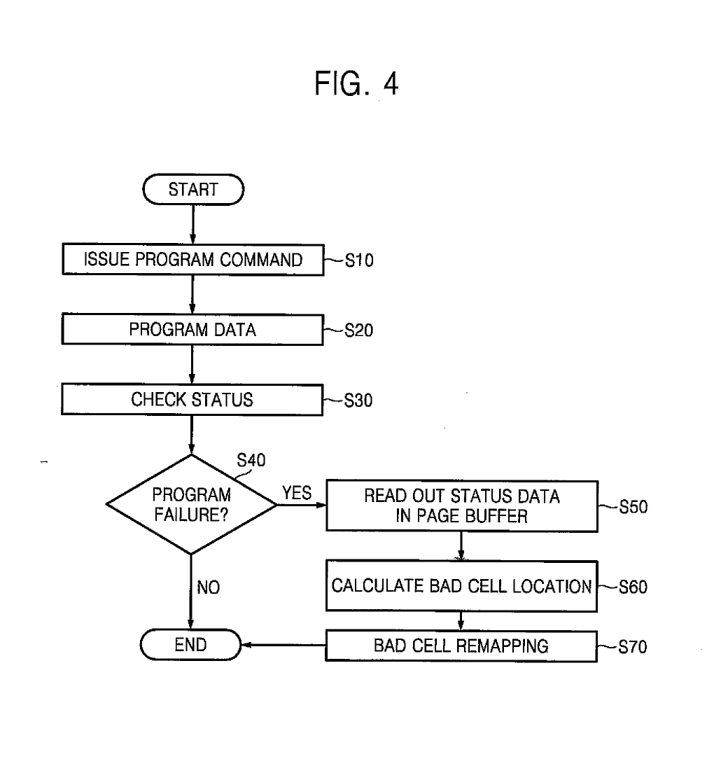

FIG. 4 is a flowchart summarizing a method for managing a bad cell according to an embodiment of the inventive concept, and FIG. 6 conceptually illustrates a bad cell remapping method according to an embodiment of the inventive concept. Referring collectively to FIGS. 1 through 6, a method replacing a bad cell identified in a main region of a page in relation to a program failure with a spare cell in a spare region within the same page will be explained.

The controller 30 provides (or issues) a program command to the memory device 20 (S10). The program command may include addresses (e.g., a row address and a column address) corresponding to write data (e.g., page data) to be programmed to the memory device 20, and the write data may be included with the program command or it may be separately provided (S20).

As is conventional, the access circuit 27 is used to program the write data in one or more page(s), (e.g., page 23-1) designated by the addresses. For example, when programming a data value of “0” to a selected memory cell, the access circuit 27 first changes the state of the selected memory cell from an erase state of “1” to the desired value of “0”, and then sets a corresponding bit of the status data in the page buffer to “1” when a programming succeeds. However, when programming a data value of “1”, the access circuit 27 places the selected memory cell to be programmed with “1” in an inhabit state. In this case, the access circuit 27 supplies a program voltage having a range of between 0V to 1.2V to a corresponding bit line according to the program data, (e.g., the page data), and supplies a program inhabit voltage having a range of between 1.8V and 2.6V to a corresponding bit line.

When all memory cells in the main region of the selected page 23-1, except for a memory cell connected to a sixth bit line are normally programmed, and the program operation is completed, then the access circuit 27 will set each bit value of status data in the page buffer to “1”, except for the 6^{th} bit of the 64 page bits, as illustrated in FIG. 2. That is, in spite of repetitive (or recursive) attempts to program the memory cell connected to the sixth bit line of the selected page, this bad cell nonetheless creates a program failure indicating that the state of the bad cell can not be reliably changed from “1” to “0”.

When the program operation is finished, the access circuit 27 is configured to provide the status data to the controller 30. For example, the memory device 20 may check the status of the program operation in response to a status check command received from the controller 30, and then communicate back to controller 30 a signal indicating whether or not a program failure as occurred (S30).

If the program operation successfully programs the write data to the one or more selected page(s) (S40=NO), the program operation ends. However, when a program failure occurs (S40=YES), the controller 30 may perform additional processing based on the contents of the status data communicated from the access circuit 27 in response to the indication signal provided from the memory device 20.

In the method of FIG. 4, the controller 30 determines the location of the bad cell by first reading the status data communicated by the access circuit 27 (S50). For example, the controller 30 may accurately detect the location of the bad cell by the location of the “0” (in case of FIG. 2) or the “1” (in case of FIG. 3) within the status data—which should be respectively and uniformly “1” and “0”. By identifying one or more erroneous bits in the status data, the controller 30 is able to calculate the location of the bad cell (S60), and undertake a remapping operation (S70).

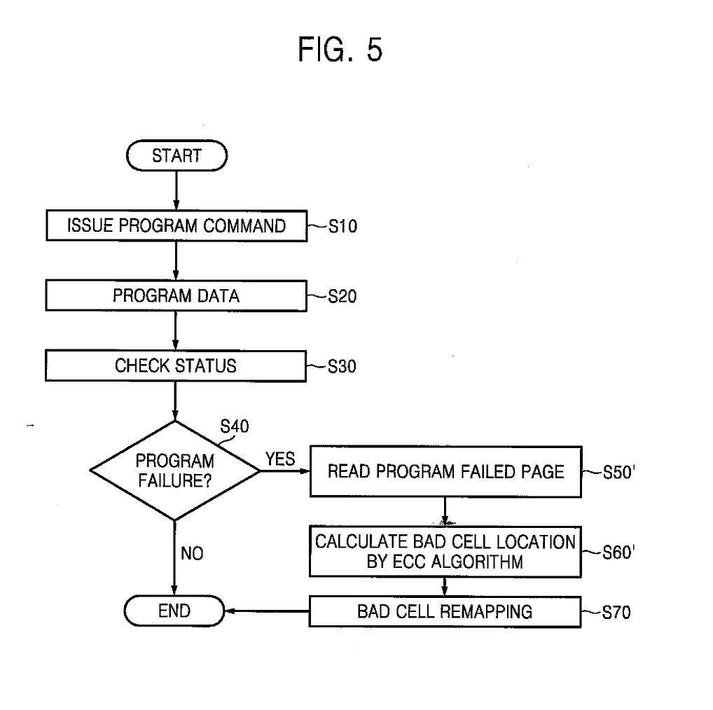

FIG. 5 is a flowchart summarizing a method for managing a bad cell according to another embodiment of the inventive concept. Here, the controller 30 reads the selected page causing the program failure (S50′), and then detects (or calculates) the location of the bad cell (failed bit) using a conventional error correction code ECC algorithm (S60′).

That is, once a program failure occurs (S40=YES), the controller 30 transmits a read command to the memory device 20 directed to a “failed page” causing the program failure (S50′). Accordingly, when the memory device 20 transmits the failed page to the controller 30 in response to the read command, the controller 30 may then detect the location of the one or more bad cell(s) (or fail bit(s)) using one or more conventionally understood error detection and/or correction (ECC) algorithm(s) (S60′). Once the location of the bad cells is calculated, the remapping operation may commence (S70).

In either approach illustrated in FIGS. 4 and 5, the FTL 33 in the controller 30 may be used to remap a bad address associated with a calculated bad cell to a spare address associated with a spare cell in the same page. That is, in certain embodiments of the inventive concept, the bad cell and the spare cell are connected by the same word line.

As illustrated in FIG. 6, the FTL 33 may not replace a runtime bad block including a plurality of bad cells with a new block, but may replace each one of a plurality of bad cells identified in a main region (MAIN REGION) with a corresponding spare cell provide in a spare region (SPARE REGION) of the same page (PAGE). Using this type of address remapping the useful life of the memory device 20 in the memory system of FIG. 1 may be extended.

A method for replacing a bad cell identified in a main region causing an erase failure with a spare cell in a spare region of the same page is substantially similar to a method for replacing a bad cell in a main region causing a program fail as explained referring to FIGS. 1 through 4 and 6 with a spare cell of a spare region in the same page, so that detailed explanation thereof is omitted.

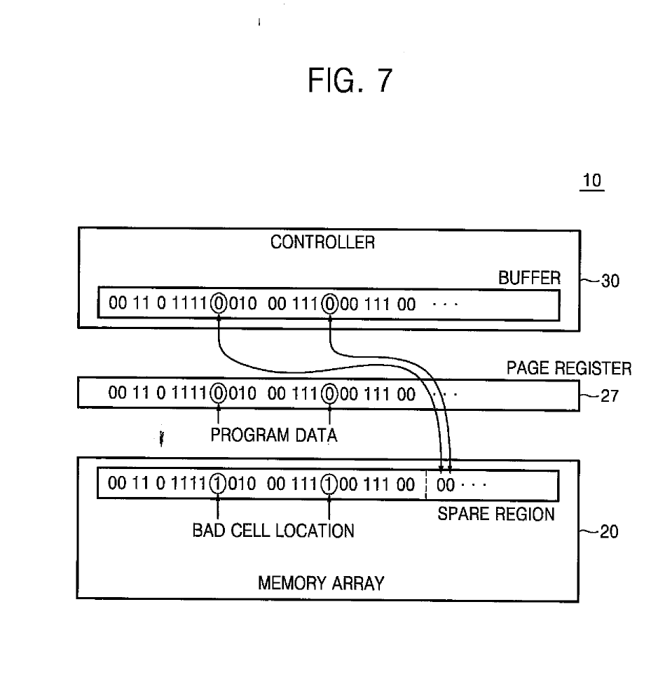

FIG. 7 conceptually illustrates an operating method for a memory system according to an embodiment of the inventive concept. After a bad address associated with a bad cell is remapped to a spare address associated with a spare cell by the controller 30 as illustrated in FIG. 7, program data stored in a buffer of the controller 30 is transmitted to the access circuit 27, (e.g., the page register 27) and the data to have been stored in the bad cell among the program data stored in the page register 27 is instead stored in the spare cell of the spare region in the same page.

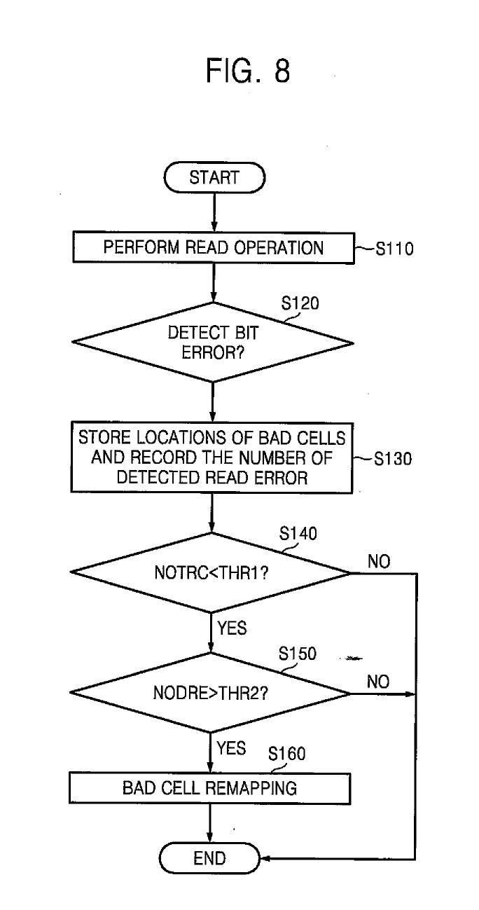

FIG. 8 is a flowchart summarizing a method for managing a bad cell according to still another embodiment of the inventive concept. Referring to FIGS. 1 through 8, the controller 30 may record the number of transmitting a read command to the memory device 20 in the controller 30 or a specific memory region of the memory device 20. For example, a specific recording region may be designated in a main region or a spare region.

The memory device 20 first performs a read operation in response to a received read command (S110). Read data (e.g., a page of read data) read from a page of a memory array 21 according to the read command is then sensed by the sense amplifier in the access circuit 27.

The controller 30 detects bad cell(s) causing read data error(s) (e.g., bad cell(s) producing fail bit(S)) from the page data transmitted from the memory 20 in response to the read command (S120), and store the respective location(s) for the bad cell(s) and records the number of detected read data error(s) caused by the bad cell(s) in the designated recording region (S130).

Recording a command number associated with a read command transmitted to the memory device 20 may be performed prior to performing the read operation (S110) or with the recording of the number of detected read data error (S130). The controller 30 then compares the command number for the read command with the command number for a reference transmission (THR1) (S140). When the command number for the read command is greater than the command number for the reference transmission (THR1) (S140=NO), the method of managing bad cell(s) is finished.

However, if the command number for the read command (NOTRC) is less than the command number of the reference transmission (THR1) (S140=YES), then the controller 30 compares the command number for detecting the read data error(s) (NODRE) with the command number for detecting a reference error (THR2) (S150). When the number of detecting the read error on the detected bad cell is less than the number of detecting the reference error (THR2) (S150=NO), the method of managing bad cell(s) is finished.

However, if the command number for detecting the read data error(s) associated with the detected bad cell(s) is greater than the command number for detecting the reference error (THR2), the controller 30 will remap a bad address associated with a detected bad cell to a spare address associated with a spare cell in the same page based on the command number of the read command and the detecting a read error.

For example, the CORE processing unit 31 of controller 20 may generate a read command, and the FTL 33 may record the command number for the read command when transmitted to the memory device 20. The FTL may then detect a bad cell causing a read data error from page data read from the memory device 20 according to the read command, and record the command number for detecting the read data error, and remap the bad address associated with the bad cell to a spare address associated with the spare cell in the same page based on the command number of the read command and the detecting of the read error.

For example, if the read operation is repeatedly directed to a selected cell, the controller 30—when the number of generating a read error in the specific cell is greater than the number of detecting a reference error THR2—may remap the address of the selected cell to a spare address in the same page, thereafter regarding the spare cell as the bad cell on a location basis.

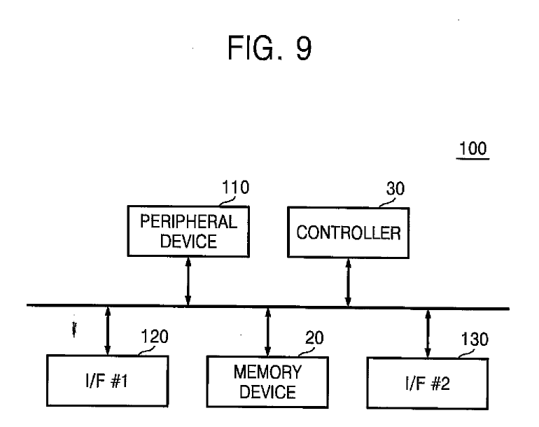

FIG. 9 is a block diagram of a memory system according to another example embodiment of the present inventive concept. Referring to FIG. 9, a memory system 100 may include a memory device 20, a controller 30 and a peripheral device 110.

The memory system 100 according to embodiments may be a computer, a memory card, a smart card, portable multimedia players (PMPs), personal digital assistants (PDAs), a MP3, a solid state disk/drive (SSD), a cellular phone, a smart phone, a digital still camera, a memory stick, a camcorder, a digital TV, or an IPTV.

The peripheral device 110 may be embodied as a camera module such as a COMS image sensor. In this case, the camera module may convert an optical signal to an electric signal and store a converted electric signal in the memory device 20 under a control of the controller 30. In addition, the memory system 100 may include at least one interface 120 or 130. A first interface 120 may be an input/output device for transmitting data input from outside to the memory device 20 under a control of the controller 30 or outputting data output from the memory device 20 to the outside.

A second interface 130 may be a wireless interface module for sending and receiving data by radio under a control of the controller 30. Accordingly, the second interface 130 may receive wireless data transmitted from outside, convert a received wireless data according to a protocol embodied in the second interface 130 and transmit a converted data to the memory device 20 or the first interface 120 under a control of the controller 30.

The second interface 130 may also convert data, which is output from the memory device 20, the peripheral device 110 or the first interface 130 under a control of the controller 30, into wireless data according to a protocol embodied in the second interface 130 and transmit a converted wireless data to outside.

Methods and related apparatuses for managing bad cell(s) according to example embodiments of the inventive concept may increase the stability of a memory system using a non-volatile memory, such as NAND flash memory, and improve the useful lifetime of the memory system.

Although a few embodiments of the present general inventive concept have been shown and described, it will be appreciated by those skilled in the art that changes may be made in these embodiments without departing from the principles of the general inventive concept, the scope of which is defined in the appended claims and their equivalents.

What is claimed is:

1. A method for managing a bad cell in a memory system comprising a controller and a memory device, wherein the memory device comprises a page buffer configured to store status data and a memory array including a plurality of pages, the method comprising:
following an operation directed to a selected page among the plurality of pages, storing the status data in the page buffer all bits of the selected page;
reading the status data from the page buffer; and
detecting a location of a bad cell in a plurality of memory cells of the memory cell array corresponding to the selected page by reference to the status data.

2. The method of claim 1, wherein the status data is generated bit for bit for all of the bits of the selected page in accordance with whether the operation has successfully defined that state of the plurality of memory cells.

3. The method of claim 2, wherein the operation is a program operation, an erase operation, or a read operation.

4. The method of claim 3, wherein each page among the plurality of pages comprises a main region and a spare region and the bad cell is located in the main region of the selected page, and the method further comprises:
remapping a bad address associated with the bad cell to a spare address associated with a spare cell in a spare region.

5. The method of claim 4, wherein the spare region is a spare region of the selected page.

6. The method of claim 1, wherein the operation is a program operation and the bad cell generates a program failure, the operation is an erase operation and the bad cell generates an erase failure, or the operation is a read operation and the bad cell generates a read failure.

7. The method of claim 1, wherein detecting the location of the bad cell is accomplished using an ECC algorithm.

8. A controller comprising:
a processing unit configured to generate a status check command and communicate the status check command to a memory device; and
a Flash Translation Layer (FTL) configured to receive status data for a selected page from a page buffer of the memory device in response to the status check command, and detect a location of a bad cell in a memory array of the memory device using the status data.

9. The controller of claim 8, wherein the FTL is further configured to remap a bad address associated with the bad cell to a spare address associated with a spare cell.

10. The controller of claim 9, wherein the FTL detects the location of the bad cell using an error an ECC algorithm.

11. A method for managing a bad cell in a memory cell array of a memory device using a controller, the method comprising:
recording a command number for a read command directed to a selected page of the memory cell array;
detecting a bad cell in the selected page generating a read error in response to the read command;
recording a number of detecting the read error caused by the bad cell; and
remapping a bad address associated with the bad cell to a spare address associated with a spare cell based on the command number of the read command and the command number of an operation detecting the read error.

12. The method of claim 11, wherein the selected page is divided into a main region containing the bad cell and a spare region containing the spare cell.

13. A controller comprising:
a processing unit configured to generate a read command and communicate the read command to a memory device; and
a flash translation layer (FTL) configured to record a command number of the read command, detect a bad cell in a selected page of a memory cell array of the memory device causing a read error for the selected page, record a command number of a command detecting the read error, and remapping a bad address associated with the bad cell to a spare address associated with a spare cell based on the command numbers of the read command and the operation detecting the read error.

14. The controller of claim 13, wherein the selected page is divided into a main region containing the bad cell and a spare region containing the spare cell.

15. In a memory system including a memory device that includes a memory cell array of non-volatile memory cells and a page buffer accessing the non-volatile memory cells, and a controller controlling operation of the memory device, a method for managing a bad cell of the controller comprises:
performing a program operation programming write data to a selected page of the memory cell array using the page buffer;
following performance of the program operation, generating status data for the selected page in accordance with results of the program operation using the page buffer; and
detecting a location of a bad cell in the memory cell array by reference to status data read from the page buffer by the controller.

16. The method of claim 15, further comprising:
remapping a bad address associated with the bad cell to a spare address associated with a spare cell using the controller.

17. The method of claim 16, wherein the selected page is divided into a main region containing the bad cell and a spare region containing the spare cell.
